(19) United States
(12) Patent Application Publication
(10) Pub. No.: US 2024/0388018 A1
(43) Pub. Date: Nov. 21, 2024

(54) LIQUID METAL PATCH INTERCONNECT FOR LARGE WARPAGE COMPONENTS

(71) Applicant: Intel Corporation, Santa Clara, CA (US)

(72) Inventors: Karumbu MEYYAPPAN, Portland, OR (US); Gregorio R. MURTAGIAN, Phoenix, AZ (US); Ziyin LIN, Jade Court, AZ (US)

(21) Appl. No.: 18/199,269

(22) Filed: May 18, 2023

(51) Int. Cl. H01R 12/52; H01L 23/498; H01R 3/08; H05K 1/18; H05K 3/32

(52) U.S. Cl. CPC H01R 12/52; H01L 23/49811; H01R 3/08; H05K 1/181; H05K 3/32; H01L 24/16; H01L 2224/16225; H05K 2201/10318; H05K 2201/10378; H05K 2201/10727

(57) ABSTRACT

Embodiments disclosed herein include an electronic package. In an embodiment, the electronic package comprises a package substrate with a first surface and a second surface opposite from the first surface. In an embodiment, pads are on the first surface of the package substrate, where the pads have a first width. In an embodiment, a layer is on the first surface of the package substrate, where the layer comprises wells through the layer, and where the wells have a second width that is wider than the first width. In an embodiment, a liquid metal is in the wells and in contact with the pads.

### TECHNICAL FIELD

Embodiments of the present disclosure relate to electronic systems, and more particularly, to electronic packages with liquid metal interconnects for substrates with large warpages.

### BACKGROUND

Electronic packaging solutions have begun to use liquid metal in socketing architectures. The liquid metal is a metallic material that is in a liquid phase at temperatures at, or around, room temperature. For example, liquid metal may comprise gallium. In a liquid metal interconnect architecture, a patch is provided on the bottom surface of the package substrate. The patch includes wells. The liquid metal is provided in the wells. Often, the wells are sealed with a cap layer. In order to allow for repeated socketing processes (e.g., for testing, upgrading, etc.) the cap layer may be a self-healing material. A pin from the board side penetrates the cap layer in order to make contact with the liquid metal.

Liquid metal socketing architectures allow for improved performance with warped or otherwise non-planar package substrates. For example, the socket pin and liquid metal patch height make up for the warpage of the mated substrates. However, large heights for the socket pin and liquid metal patch result in high Z-heights. Larger Z-heights affect signal integrity. Ultimately, such architectures are not suitable replacements for a typical ball grid array (BGA) solution. For example, the sockets may result in Z-heights that are approximately 2.0 mm or greater.

### BRIEF DESCRIPTION OF THE DRAWINGS

FIG. 1A is a cross-sectional illustration of a traditional liquid metal socket interconnect before the board is attached to the package substrate, in accordance with an embodiment.

FIG. 1B is a cross-sectional illustration of the liquid metal socket interconnect with the board attached to the package substrate, in accordance with an embodiment.

FIG. 2A is a cross-sectional illustration of an electronic package with a warped package substrate, in accordance with an embodiment.

FIG. 2B is a cross-sectional illustration of an electronic package with a warped package substrate that is coupled to a board with a liquid metal interconnect that does not use a pin, in accordance with an embodiment.

FIG. 3A is a cross-sectional illustration of an electronic package with a higher order warped package substrate, in accordance with an embodiment.

FIG. 3B is a cross-sectional illustration of an electronic package with a warped package that is coupled to a board with a liquid metal interconnect that does not use a pin, in accordance with an embodiment.

FIG. 4A is a cross-sectional illustration of a compressible liquid metal patch, in accordance with an embodiment.

FIG. 4B is a cross-sectional illustration of the liquid metal patch in a compressed state, in accordance with an embodiment.

FIG. 5A is a cross-sectional illustration of a liquid metal patch aligned over a board, in accordance with an embodiment.

FIG. 5B is a cross-sectional illustration of the liquid metal patch coupled to the board, in accordance with an embodiment.

FIG. 5C is a cross-sectional illustration of the liquid metal patch after a liquid metal is dispensed in the wells, in accordance with an embodiment.

FIG. 5D is a cross-sectional illustration of the liquid metal patch after a liquid metal is inserted with a screen printing process, in accordance with an embodiment.

FIG. 6A is a cross-sectional illustration of a liquid metal patch with a liquid metal within wells of the liquid metal patch, in accordance with an embodiment.

FIG. 6B is a cross-sectional illustration of the liquid metal patch coupled to a board, in accordance with an embodiment.

FIG. 7A is a cross-sectional illustration of an electronic package with a liquid metal patch before the package substrate is coupled to the board, in accordance with an embodiment.

FIG. 7B is a cross-sectional illustration of the electronic package with the package substrate coupled to the board with a liquid metal patch that includes reservoirs for excess liquid metal, in accordance with an embodiment.

FIG. 8A is a cross-sectional illustration of an electronic package with a liquid metal patch that includes reservoirs within the patch before the package substrate is coupled to the board, in accordance with an embodiment.

FIG. 8B is a cross-sectional illustration of the electronic package with the package substrate coupled to the board with a liquid metal patch that includes internal reservoirs for excess liquid metal, in accordance with an embodiment.

FIG. 9A is a cross-sectional illustration of an electronic package with a liquid metal patch before the package substrate is coupled to the board, where the liquid metal includes voids, in accordance with an embodiment.

FIG. 9B is a cross-sectional illustration of the electronic package with the package substrate coupled to the board where liquid metal voids are coalesced, in accordance with an embodiment.

FIG. 10 is a schematic of a computing device built in accordance with an embodiment.

### EMBODIMENTS OF THE PRESENT DISCLOSURE

Described herein are electronic systems, and more particularly, electronic packages with liquid metal interconnects for substrates with large warpages, in accordance with various embodiments. In the following description, various aspects of the illustrative implementations will be described using terms commonly employed by those skilled in the art to convey the substance of their work to others skilled in the art. However, it will be apparent to those skilled in the art that the present invention may be practiced with only some of the described aspects. For purposes of explanation, specific numbers, materials and configurations are set forth in order to provide a thorough understanding of the illustrative implementations. However, it will be apparent to one skilled in the art that the present invention may be practiced without the specific details. In other instances, well-known features are omitted or simplified in order not to obscure the illustrative implementations.

Various operations will be described as multiple discrete operations, in turn, in a manner that is most helpful in understanding the present invention, however, the order of description should not be construed to imply that these operations are necessarily order dependent. In particular, these operations need not be performed in the order of presentation.

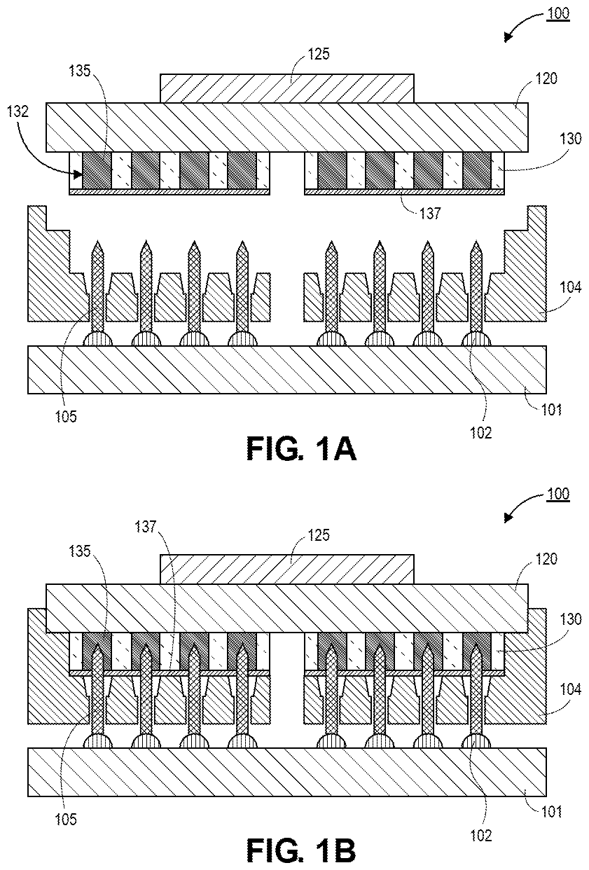

Referring now to FIG. 1A, a cross-sectional illustration of an electronic package 100 before a package substrate 120 is coupled to a board 101 is shown. The electronic package 100 may utilize a liquid metal socket architecture in order to couple the package substrate 120 to the board 101. The package substrate 120 may include a die 125 on a top side and a liquid metal patch 130 on a bottom side. The liquid metal patch 130 may be any suitable material, such as a polymer or the like. A plurality of wells 132 may be provided through the liquid metal patch 130. The wells 132 are filled with a liquid metal 135. A cap layer 137 may be provided across the wells 132 in order to confine the liquid metal 135 within the wells 132. The cap layer 137 may be a polymer material, such as a self-healing polymer.

The board 101 side of the electronic package 100 may include pins 105. The pins 105 may be coupled to the board 101 by a solder 102 or other electrical and mechanical coupling solution. A frame 104 may be provided around the pins 105. The pins 105 may be high aspect ratio features. The end of the pins 105 may be pointed in order to more easily pierce the cap layer 137.

Referring now to FIG. 1B, a cross-sectional illustration of the electronic package 100 after the board 101 is coupled to the package substrate 120 is shown. The package substrate 120 may be electrically coupled to the board 101 by the pins 105. For example, the pins 105 may pierce the cap layer 137 and contact the liquid metal 135.

In the illustration of FIG. 1B, the package substrate 120 and the board 101 are perfectly flat. That is, there is no warpage in the package substrate 120 or the board 101. In such an instance, each pin 105 has a uniform surface area in contact with the liquid metal 135. However, as one or both of the package substrate 120 and the board 101 begin to warp, the surface area in contact with the liquid metal 135 changes. For example, the surface area of the interface between the liquid metal 135 and the pin 105 may be high at an edge of the electronic package 100 and low at a center of the electronic package 100. In some instances, the warpage may be extreme, and one or more of the pins 105 may not make any contact with the liquid metal. In order to prevent electrical opens caused by warpage, the thickness of the liquid metal patch 130 and/or the height of the pins 105 may be increased. This negatively impacts the Z-height of the electronic package 100, and is not compatible with some applications that use a low Z-height structure (e.g., mobile devices).

Accordingly, embodiments disclosed herein include a liquid metal interconnect solution that omits the use of a pin. Instead, the liquid metal patch is provided on the package substrate, and the liquid metal directly contacts the pad on the opposing board. The liquid metal patch may be a compressible material. As such, the patch conforms to different warpages of the package substrate and/or the board. In some embodiments, reservoirs may be provided in or around the liquid metal patch. As such, excess liquid metal can be accommodated without negatively impacting the interconnect architecture.

In addition to accommodating warped substrates, embodiments allow for lower Z-heights compared to pin-based interconnect architectures. Low Z-heights (along with a wider cross-section) allow for improved electrical performance. Also, thin and light components that are compatible with form factor restricted applications (such as mobile devices) are enabled. Further, the elimination of the socket pins and cap layer significantly reduces costs of the electronic package.

Further, while embodiments disclosed herein refer to substrates that are coupled together as being a “package substrate” and a “board”, it is to be appreciated that the liquid metal patches disclosed herein can be applied to any two substrates that are to be coupled together. In this way, components can be connected and/or detached similar to an interlocking blocks. More generally, liquid metal patches disclosed herein allow for small height interconnects that accommodate any warpage between connected components.

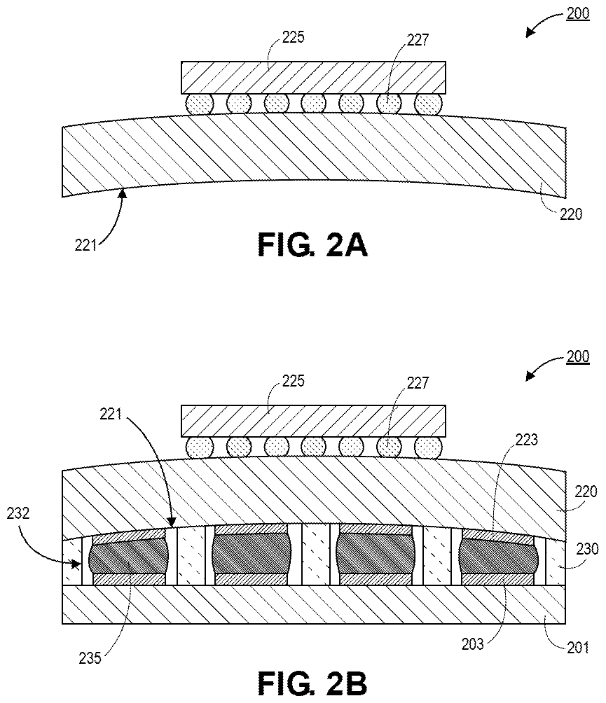

Referring now to FIG. 2A, a cross-sectional illustration of an electronic package 200 is shown, in accordance with an embodiment. As shown, the electronic package 200 may comprise a package substrate 220. The package substrate 220 may comprise buildup layers, such as organic buildup film. In some embodiments, the package substrate 220 may comprise a core (not shown) or the like. The package substrate 220 may include conductive routing, such as pads, traces, vias, etc.

A die 225 may be coupled to the package substrate 220. For example, interconnects 227 may couple the package substrate 220 to the die 225. The interconnects 227 may be solder interconnects or any other suitable first level interconnect (FLI) architecture. The die 225 may be a compute die, such as a central processing unit (CPU), a graphics processing unit (GPU), an XPU, a system on a chip (SoC), a communications die, a memory, or the like. While a single die 225 is shown in FIG. 2A, it is to be appreciated that two or more dies 225 may be included on the package substrate 220 in some embodiments.

In an embodiment, the package substrate 220 may be warped. For example, the bottom surface 221 may be non-planar. In the particular embodiment shown in FIG. 2A, the package substrate 220 is warped so that the bottom surface 221 has a single curve. For example, the bottom surface 221 may be warped in a concave shape. Though, in other embodiments, the bottom surface 221 may be warped in the opposite direction (i.e., convex).

Referring now to FIG. 2B, a cross-sectional illustration of an electronic package 200 after a board 201 is attached to the package substrate 220 is shown, in accordance with an embodiment. In an embodiment, the package substrate 220 may be coupled to the board 201 through a liquid metal patch 230. The liquid metal patch 230 may include wells 232. Liquid metal 235 may be provided within the wells 232. The liquid metal 235 may electrically couple pads 203 on the board to the pads 223 on the package substrate 220. As used herein, “liquid metal” refers to an electrically conductive material that is in the liquid phase at (or around) room temperature. In some instances, the liquid metal may maintain a liquid phase at temperatures down to zero degrees Celsius. In an embodiment, the liquid metal 235 may comprise gallium with or without any other alloying elements.

The warped bottom surface 221 of the package substrate 220 may be accommodated by the liquid metal patch 230. For example, the liquid metal patch 230 may be a conformable or otherwise compressible material. As shown, the edges of the liquid metal patch 230 may be compressed more than a center of the liquid metal patch 230. Of course, different warpages of the package substrate 220 may also be accommodated by the compressible liquid metal patch 230. In the illustrated embodiment, the board 201 is not warped. Though, in other embodiments, the board 201 may also be warped. In such instances, the liquid metal patch 230 may accommodate the warpage of both the package substrate 220 and the board 201. In the illustrated embodiment, the liquid metal 235 is defined by the metal pads 203 and 223. Though, in other embodiments, the liquid metal 235 may substantially fill the wells 232 between the package substrate 220 and the board 201.

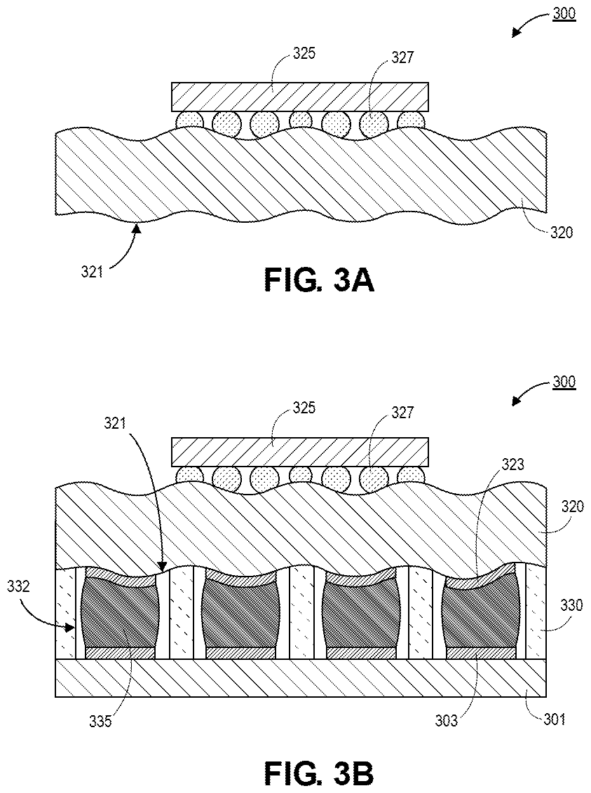

Referring now to FIG. 3A, a cross-sectional illustration of an electronic package 300 is shown, in accordance with an additional embodiment. The electronic package 300 may be similar to the electronic package 200 in FIG. 2A, with the exception of the warpage. Instead of a single curve, the warpage of the bottom surface 321 may be a higher order warpage. Such an embodiment may be the result of plating density differences or assembly and/or handling induced deformations.

A die 325 may be coupled to the top surface of the package substrate 320 by interconnects 327. In an embodiment, the die 325 may be similar to the die 225 described in greater detail above. Further, embodiments may include two or more dies 325 coupled to the package substrate 320.

Referring now to FIG. 3B, a cross-sectional illustration of the electronic package 300 with a board 301 coupled to the package substrate 320 is shown, in accordance with an embodiment. As shown, a liquid metal patch 330 may be provided between the bottom surface 321 of the package substrate 320 and the board 301. In a particular embodiment, the liquid metal patch 330 may be a conformable material in order to accommodate the warpage of the package substrate 320. Liquid metal 335 within wells 332 of the liquid metal patch 330 may provide an electrical connection between pads 323 of the package substrate 320 and pads 303 of the board 301. The liquid metal 335 may be similar to the liquid metal 235 described in greater detail above. In the illustrated embodiment, the liquid metal 335 is defined by the metal pads 303 and 323. Though, in other embodiments, the liquid metal 335 may substantially fill the wells 332 between the package substrate 320 and the board 301.

In the illustrated embodiment, the electronic package 300 includes a board 301 that is not warped. Though, in other embodiments, the board 301 may also include warpage. Even when the board 301 and the package substrate 320 are warped, the liquid metal patch 330 and the liquid metal 335 conform to the warped surfaces.

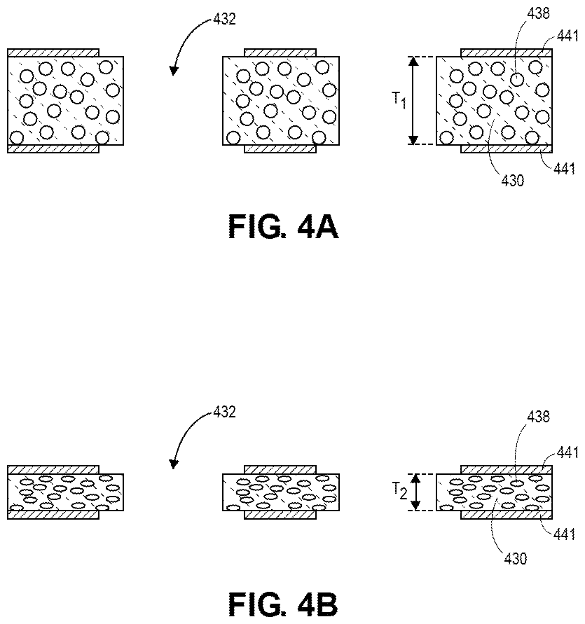

Referring now to FIG. 4A, a cross-sectional illustration of a liquid metal patch 430 is shown, in accordance with an embodiment. As shown, the liquid metal patch 430 may include one or more wells 432. The wells 432 may be openings that pass through an entire thickness of the liquid metal patch 430. In an embodiment, the wells 432 may be formed with a laser drilling process or through being mechanically punched. In an embodiment, the liquid metal patch 430 may have a thickness T₁. The thickness T₁ may be up to approximately 20 μm or greater, or up to approximately 100 μm or greater.

In an embodiment, adhesive 441 may be provided over the top and bottom surfaces of the liquid metal patch 430. The edges of the adhesive 441 may be recessed from the edges of the wells 432. That is, portions of the top and bottom surface of the liquid metal patch 430 may be exposed.

In an embodiment, the liquid metal patch 430 may comprise a compressible material. For example, the liquid metal patch 430 may comprise a compressible polymer, such as a rubber, silicone, or other hyperelastic material, or a soft compliant material. In other embodiments, the liquid metal patch 430 may comprise foam material. In a particular embodiment, the foam may be a closed cell foam. For example, voids 438 may be provided through a thickness of the liquid metal patch 430.

Referring now to FIG. 4B, a cross-sectional illustration of the liquid metal patch 430 in a compressed state is shown, in accordance with an embodiment. In an embodiment, the liquid metal patch 430 may be compressed to a thickness T₂ that is less than the thickness T₁.

In the illustrated embodiment, the liquid metal patch 430 is uniformly compressed. However, it is to be appreciated that the liquid metal patch 430 may have a non-uniform compression. As such, the liquid metal patch 430 is capable of conforming to warped substrates, such as those described in greater detail above.

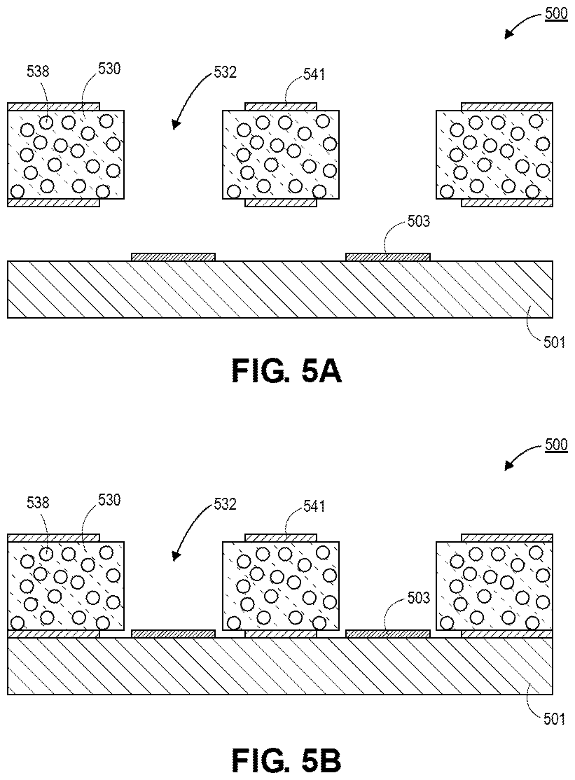

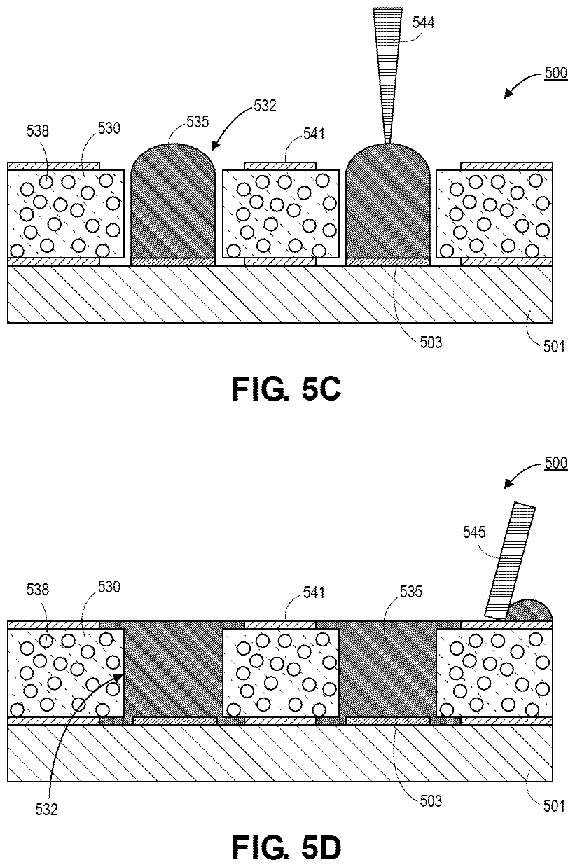

Referring now to FIGS. 5A-5D, a series of cross-sectional illustrations depicting a process for attaching a liquid metal patch 530 to a board 501 in an electronic package 500 is shown, in accordance with an embodiment.

Referring now to FIG. 5A, a cross-sectional illustration of a liquid metal patch 530 that is provided above a board 501 is shown, in accordance with an embodiment. The liquid metal patch 530 may be similar to the liquid metal patches described in greater detail above. For example, the liquid metal patch 530 may be a compressible material. In one embodiment, the liquid metal patch 530 may include a foam with voids 538. The liquid metal patch 530 may also comprise wells 532 formed through a thickness of the liquid metal patch 530. In an embodiment, the wells 532 may be aligned over pads 503 on the board 501. A width of the wells 532 may be greater than a width of the pads 503. Embodiments may further comprise an adhesive 541 over the top and bottom surfaces of the liquid metal patch 530. The edges of the adhesive 541 may be recessed from edges of the wells 532 so that portions of the top and bottom surfaces of the liquid metal patch 530 may be exposed.

Referring now to FIG. 5B, a cross-sectional illustration of the electronic package 500 is shown, in accordance with an embodiment. As shown, the liquid metal patch 530 is attached to the top surface of the board 501. For example, adhesive 541 may mechanically couple the liquid metal patch 530 to the board 501. The pads 503 may be aligned with the wells 532 through the liquid metal patch 530. In an embodiment, a thickness of the adhesive 541 may be substantially equal to a thickness of the pads 503. Though, in other embodiments, the adhesive 541 may have a thickness that is less than the thickness of the pads 503 or greater than a thickness of the pads 503.

Referring now to FIG. 5C, a cross-sectional illustration of the electronic package 500 after a liquid metal 535 is dispensed in the wells 532 is shown, in accordance with an embodiment. The liquid metal 535 may be dispensed into the wells 532 with liquid injection process. For example, a needle 544 may be used to dispense the liquid metal 535. In an embodiment, the liquid metal 535 may comprise gallium or gallium with other alloying elements. In an embodiment, the liquid metal 535 may be provided over the pads 503. The liquid metal 535 may not entirely fill the wells 532 in some embodiments.

Referring now to FIG. 5D, a cross-sectional illustration of the electronic package 500 using an alternate liquid metal deposition process is shown, in accordance with an embodiment. Instead of using a needle 544, embodiments may include a screen printing process with a squeegee 545 that move across the top surface of the liquid metal patch 530. In such embodiments, the liquid metal 535 may fully fill the wells 532. For example, the liquid metal 535 may be provided in the reservoirs around the pads 503. Additionally, the top of the liquid metal 535 may be substantially coplanar with a top surface of the adhesive 541.

In an embodiment, the processing may continue after FIG. 5C or FIG. 5D by attaching a package substrate (not shown) to the liquid metal patch 530. For example, the liquid metal patch 530 may be mechanically coupled to the package substrate by the top adhesive 541. Pads on the package substrate may be in direct contact with the liquid metal 535. The conformable nature of the liquid metal patch 530 allows for accommodation to any warpage in the overlying package substrate or the underlying board 501.

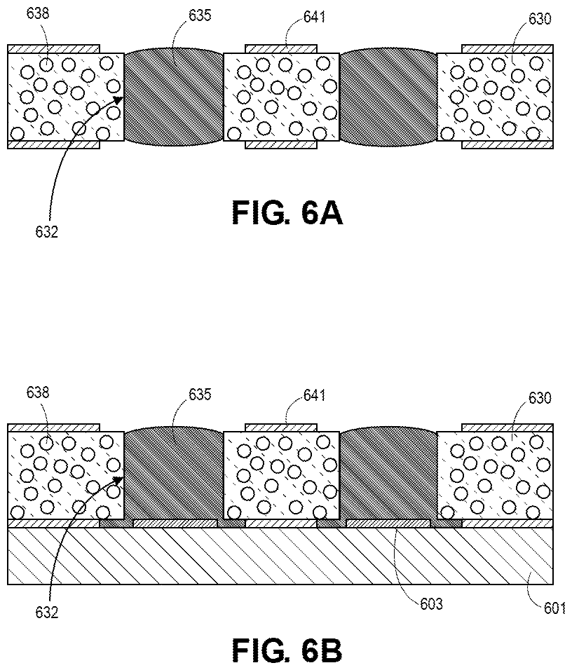

Referring now to FIG. 6A, a cross-sectional illustration of a liquid metal patch 630 is shown, in accordance with an additional embodiment. In an embodiment, the liquid metal patch 630 may be a conformable material, such as those described in greater detail above. For example, the liquid metal patch 630 may be a foam with voids 638. The liquid metal patch 630 may compress by up to approximately 80 percent in some embodiments. Adhesives 641 may be provided over a top and bottom surface of the liquid metal patch 630.

In an embodiment, the liquid metal patch 630 may comprise one or more wells 632. The wells 632 may pass entirely through a thickness of the liquid metal patch 630. The wells 632 may be fully filled with a liquid metal 635. The liquid metal 635 may be similar to any of the liquid metals described in greater detail above. The liquid metal 635 may have a high surface tension. As such, the liquid metal 635 may be confined to the wells 632. That is, the liquid metal 635 does not leak out of the liquid metal patch 630 even though there is no capping layer across the liquid metal patch 630.

Referring now to FIG. 6B, a cross-sectional illustration of the liquid metal patch 630 coupled to a board 601 is shown, in accordance with an embodiment. The liquid metal patch 630 may be coupled to the board 601 by the adhesive 641. In an embodiment, the wells 632 are aligned over pads 603 of the board 601. As such, the liquid metal 635 may directly contact the pads 603. Since the pads 603 extend up from the surface of the substrate 601, the liquid metal 635 may be provided over sidewall surfaces and top surfaces of the pads 603. The liquid metal 635 may also fill reservoirs adjacent to the pads 603.

After the liquid metal patch 630 is coupled to the board 601 a package substrate (not shown) may be attached to the top of the liquid metal patch 630. Due to the conformability of the liquid metal patch 630, warpage in one or both of the board 601 and the package substrate may be accommodated.

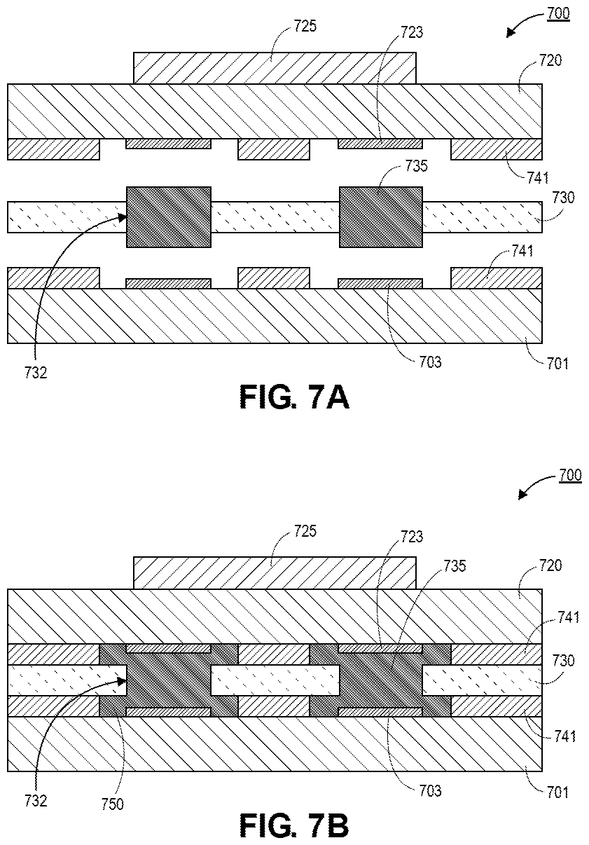

In addition to conformable materials for the liquid metal patch, embodiments may include reservoirs in order to accommodate excess liquid metal. As such, the wells through the liquid metal patch can be overfilled. This provides more flexibility to accommodate warpage of one or both of the package substrate and the board. Examples of reservoir architectures are shown in FIG. 7A-9B.

Referring now to FIG. 7A, a cross-sectional illustration of an electronic package 700 before the package substrate 720 is coupled to the board 701 is shown, in accordance with an embodiment. In an embodiment, the package substrate 720 may comprise one or more dies 725 on the top side. Pads 723 may be provided on the bottom side of the package substrate 720. An adhesive 741 may also be provided along the bottom side of the package substrate 720. In an embodiment, pads 703 may be provided over a top surface of the board 701. An adhesive 741 may also be provided over the top surface of the board 701.

In an embodiment, a liquid metal patch 730 may be provided between the board 701 and the package substrate 720. The liquid metal patch 730 may comprise an electrically insulating material, such as a polymer or the like. In some embodiments, the liquid metal patch 730 may be compressible. The liquid metal patch 730 may comprise wells 732 through a thickness of the liquid metal patch 730. The wells 732 may be filled with a liquid metal 735. For example, the liquid metal 735 may be a material similar to any of the liquid metals described in greater detail above. As shown, the volume of the liquid metal 735 may be larger than the volume of the wells 732. The excess volume of liquid metal 735 may be formed through the use of a liner or stencil over the liquid metal patch 730. The liquid metal 735 is dispensed (e.g., with screen printing or injection) and the liner or stencil is then removed.

Referring now to FIG. 7B, a cross-sectional illustration of the electronic package 700 after the board 701 is attached to the package substrate 720 is shown, in accordance with an embodiment. In an embodiment, the excess liquid metal 735 may flow into the reservoirs 750 that are provided adjacent to the pads 703 and 723. The excess volume allows for warpage between the package substrate 720 and the board 701 to be accommodated without extruding the liquid metal 735 out of the wells 732. Accordingly, an electrical connection between the pads 703 and the pads 723 can be provided by the liquid metal 735 without the need for pins.

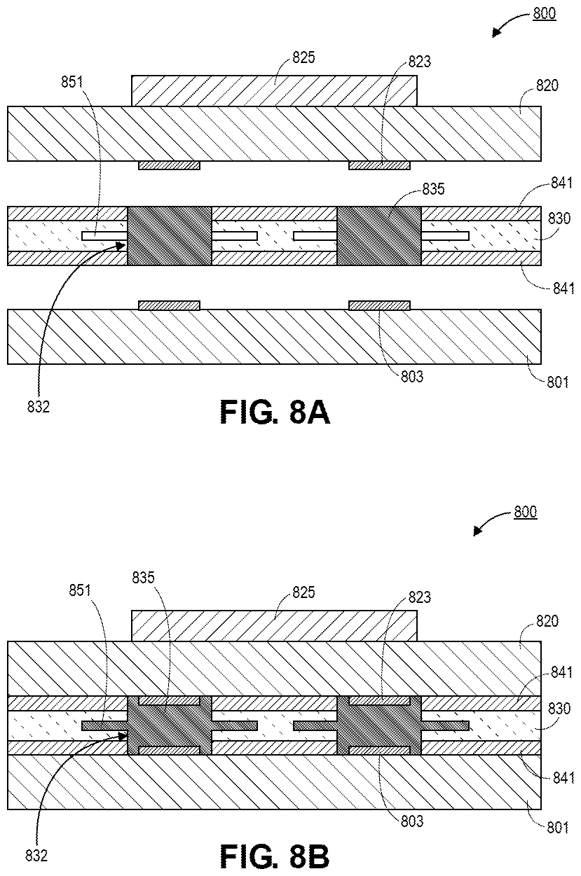

Referring now to FIG. 8A, a cross-sectional illustration of an electronic package 800 before the package substrate 820 is coupled to the board 801 is shown, in accordance with an embodiment. In an embodiment, the package substrate 820 may comprise one or more dies 825 on the top side. Pads 823 may be provided on the bottom side of the package substrate 820. In an embodiment, pads 803 may be provided over a top surface of the board 801.

In an embodiment, a liquid metal patch 830 is provided between the package substrate 820 and the board 801. The liquid metal patch 830 may comprise an electrically insulating material, such as a polymer or the like. In some embodiments, the liquid metal patch 830 may be compressible. The liquid metal patch 830 may comprise wells 832 through a thickness of the liquid metal patch 830. The wells 832 may be filled with a liquid metal 835. For example, the liquid metal 835 may be a material similar to any of the liquid metals described in greater detail above. As shown, the volume of the liquid metal 835 may be larger than the volume of the wells 832. Adhesives 841 may be provided above and below the liquid metal patch 830.

In an embodiment, reservoirs 851 may be provided within the liquid metal patch 830. The reservoirs 851 may be formed using a multilayer patch with different dimensions. For example, a first and third layer may have openings with a width that sets the edge of the wells 832. A second layer between the first layer and the third layer may have an opening that is wider than the openings for the wells 832. In other embodiments, injection molded plastic with holes can be used as the reservoirs 851.

Referring now to FIG. 8B, a cross-sectional illustration of the electronic package after the package substrate 820 is coupled to the board 801 is shown, in accordance with an embodiment. In an embodiment, attachment of the board 801 to the package substrate 820 may compress the liquid metal 835. As such, the reservoirs 851 may be at least partially filled by the liquid metal 835. Such an embodiment allows for electrical coupling between the pads 823 and 803 using a liquid metal 835 without pins. Additionally, the excess volume provided by the reservoirs 851 allows for compatibility with warped substrates.

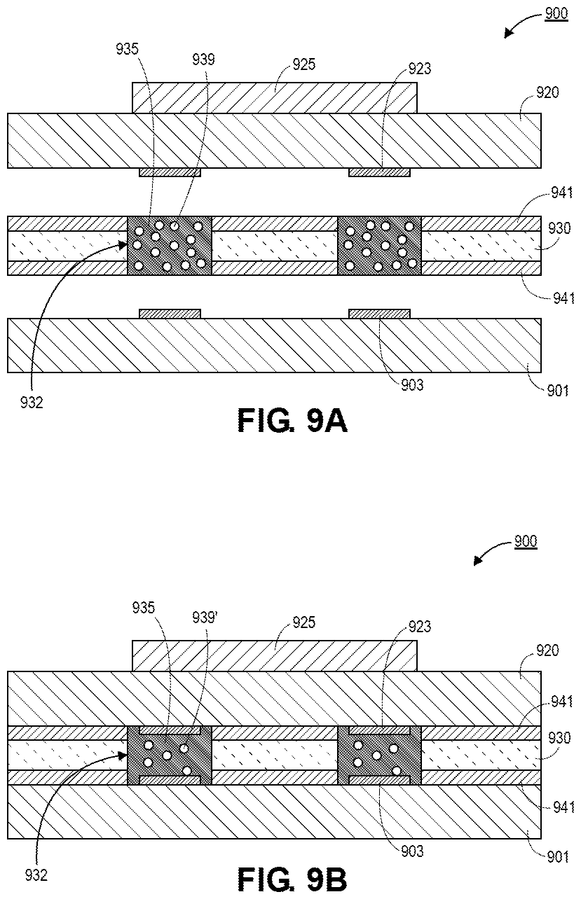

Referring now to FIG. 9A, a cross-sectional illustration of an electronic package 900 before the package substrate 920 is coupled to the board 901 is shown, in accordance with an embodiment. In an embodiment, the package substrate 920 may comprise one or more dies 925 on the top side. Pads 923 may be provided on the bottom side of the package substrate 920. In an embodiment, pads 903 may be provided over a top surface of the board 901.

In an embodiment, a liquid metal patch 930 is provided between the package substrate 920 and the board 901. The liquid metal patch 930 may comprise an electrically insulating material, such as a polymer or the like. In some embodiments, the liquid metal patch 930 may be compressible. The liquid metal patch 930 may comprise wells 932 through a thickness of the liquid metal patch 930. The wells 932 may be filled with a liquid metal 935. For example, the liquid metal 935 may be a material similar to any of the liquid metals described in greater detail above. More particularly, the liquid metal 935 may be include voids 939 or compressible fillers. In an embodiment, the voids 939 may comprise up to approximately 20 percent of the volume of the liquid metal 935. Voids 939 may be integrated into the liquid metal 935 using vortex mixing. Adhesives 941 may be provided above and below the liquid metal patch 930.

Referring now to FIG. 9B, a cross-sectional illustration of the electronic package 900 after the board 901 is coupled to the package substrate 920 is shown, in accordance with an embodiment. In an embodiment, the liquid metal 935 may be compressed in order to accommodate warpage of one or both of the board 901 and the package substrate 920. The compression of the liquid metal 935 may result in the voids 939 coalescing to form voids 939′. Accordingly, pads 923 are electrically coupled to pads 903 by a liquid metal 935 without the use of pins.

Therefore, embodiments described herein allow for various liquid metal coupling architectures that allow for electrical coupling without pins while still being able to accommodate warpage of one or both substrates. The warpage may be accommodated through the use of one or both of compressible liquid metal patches and reservoirs. As such, embodiments provide electrical coupling architectures that are suitable alternatives for ball grid array (BGA) architectures.

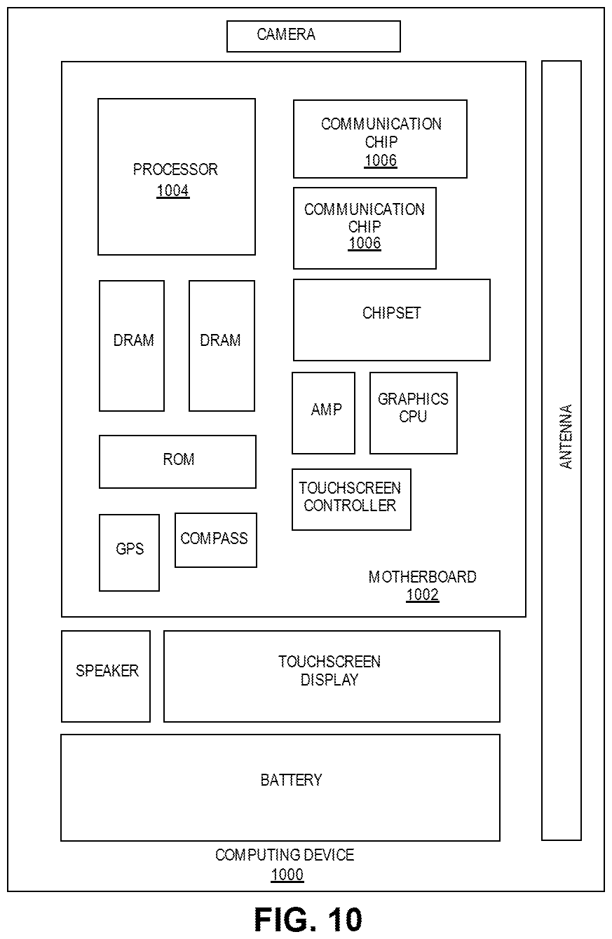

FIG. 10 illustrates a computing device 1000 in accordance with one implementation of the invention. The computing device 1000 houses a board 1002. The board 1002 may include a number of components, including but not limited to a processor 1004 and at least one communication chip 1006. The processor 1004 is physically and electrically coupled to the board 1002. In some implementations the at least one communication chip 1006 is also physically and electrically coupled to the board 1002. In further implementations, the communication chip 1006 is part of the processor 1004.

These other components include, but are not limited to, volatile memory (e.g., DRAM), non-volatile memory (e.g., ROM), flash memory, a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth).

The communication chip 1006 enables wireless communications for the transfer of data to and from the computing device 1000. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 1006 may implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing device 1000 may include a plurality of communication chips 1006. For instance, a first communication chip 1006 may be dedicated to shorter range wireless communications such as Wi-Fi and Bluetooth and a second communication chip 1006 may be dedicated to longer range wireless communications such as GPS, EDGE, GPRS, CDMA, WiMAX, LTE, Ev-DO, and others.

The processor 1004 of the computing device 1000 includes an integrated circuit die packaged within the processor 1004. In some implementations of the invention, the integrated circuit die of the processor may be part of an electronic package with a liquid metal patch that enables electrical coupling with liquid metal without a pin, in accordance with embodiments described herein. The term “processor” may refer to any device or portion of a device that processes electronic data from registers and/or memory to transform that electronic data into other electronic data that may be stored in registers and/or memory.

The communication chip 1006 also includes an integrated circuit die packaged within the communication chip 1006. In accordance with another implementation of the invention, the integrated circuit die of the communication chip may be part of electronic package with a liquid metal patch that enables electrical coupling with liquid metal without a pin, in accordance with embodiments described herein.

In an embodiment, the computing device 1000 may be part of any apparatus. For example, the computing device may be part of a personal computer, a server, a mobile device, a tablet, an automobile, or the like. That is, the computing device 1000 is not limited to being used for any particular type of system, and the computing device 1000 may be included in any apparatus that may benefit from computing functionality.

The above description of illustrated implementations of the invention, including what is described in the Abstract, is not intended to be exhaustive or to limit the invention to the precise forms disclosed. While specific implementations of, and examples for, the invention are described herein for illustrative purposes, various equivalent modifications are possible within the scope of the invention, as those skilled in the relevant art will recognize.

These modifications may be made to the invention in light of the above detailed description. The terms used in the following claims should not be construed to limit the invention to the specific implementations disclosed in the specification and the claims. Rather, the scope of the invention is to be determined entirely by the following claims, which are to be construed in accordance with established doctrines of claim interpretation.

Example 1: an electronic package, comprising: a package substrate with a first surface and a second surface opposite from the first surface; a pad on the first surface of the package substrate, wherein the pad has a first width; a layer on the first surface of the package substrate, wherein the layer comprises a well through the layer, wherein the well has a second width that is wider than the first width; and a metallic material in the well and in contact with the pad, the metallic material comprising gallium.

Example 2: the electronic package of Example 1, wherein the layer comprises a foam.

Example 3: the electronic package of Example 2, wherein the foam is a closed cell foam.

Example 4: the electronic package of Examples 1-3, wherein the layer comprises silicone.

Example 5: the electronic package of Examples 1-4, wherein the metallic material comprises gallium alloyed with at least one other metal.

Example 6: the electronic package of Examples 1-5, wherein the first surface of the package substrate is non-planar, and wherein the layer conforms to a profile of the first surface of the package substrate.

Example 7: the electronic package of Examples 1-6, wherein an adhesive is provided between the package substrate and the layer.

Example 8: the electronic package of Examples 1-7, further comprising: a board on a surface of the layer opposite from the package substrate; and a second pad on the board, wherein the liquid metal directly contacts the second pad.

Example 9: the electronic package of Example 8, wherein the second width is greater than a third width of the second pad.

Example 10: the electronic package of Example 9, wherein the liquid metal contacts top surfaces and sidewall surfaces of the second pad.

Example 11: an electronic package, comprising: a first substrate with a first pad; a second substrate with a second pad; a layer between the first substrate and the second substrate, wherein the layer comprises a well through the layer; and a liquid metal in the well, wherein the liquid metal contacts the first pad and the second pad.

Example 12: the electronic package of Example 11, further comprising: a reservoir fluidically coupled to the well.

Example 13: the electronic package of Example 12, wherein the reservoir is provided adjacent to the first pad and the second pad.

Example 14: the electronic package of Example 12 or Example 13, wherein the reservoir is a channel into the layer.

Example 15: the electronic package of Examples 11-14, wherein the liquid metal has voids.

Example 16: the electronic package of Example 15, wherein the voids account for up to approximately 20% of the volume of the liquid metal.

Example 17: the electronic package of Examples 11-16, wherein the first substrate is a package substrate and the second substrate is a board.

Example 18: an electronic system, comprising: a board with a first pad; a package substrate with a second pad electrically coupled to the board by a liquid metal that contacts the first pad and the second pad; and a die coupled to the package substrate.

Example 19: the electronic system of Example 18, further comprising: a layer between the board and the package substrate, wherein the layer comprises a well that confines the liquid metal.

Example 20: the electronic system of Example 18 or Example 19, wherein the electronic system is part of a personal computer, a server, a mobile device, a tablet, or an automobile.

What is claimed is:

1. An electronic package, comprising:
a package substrate with a first surface and a second surface opposite from the first surface;
a pad on the first surface of the package substrate, wherein the pad has a first width;
a layer on the first surface of the package substrate, wherein the layer comprises a well through the layer, wherein the well has a second width that is wider than the first width; and
a metallic material in the well and in contact with the pad, the metallic material comprising gallium.

2. The electronic package of claim 1, wherein the layer comprises a foam.

3. The electronic package of claim 2, wherein the foam is a closed cell foam.

4. The electronic package of claim 1, wherein the layer comprises silicone.

5. The electronic package of claim 1, wherein the metallic material comprises gallium alloyed with at least one other metal.

6. The electronic package of claim 1, wherein the first surface of the package substrate is non-planar, and wherein the layer conforms to a profile of the first surface of the package substrate.

7. The electronic package of claim 1, wherein an adhesive is provided between the package substrate and the layer.

8. The electronic package of claim 1, further comprising:
a board on a surface of the layer opposite from the package substrate; and
a second pad on the board, wherein the liquid metal directly contacts the second pad.

9. The electronic package of claim 8, wherein the second width is greater than a third width of the second pad.

10. The electronic package of claim 9, wherein the liquid metal contacts top surfaces and sidewall surfaces of the second pad.

11. An electronic package, comprising:
a first substrate with a first pad;
a second substrate with a second pad;
a layer between the first substrate and the second substrate, wherein the layer comprises a well through the layer; and
a liquid metal in the well, wherein the liquid metal contacts the first pad and the second pad.

12. The electronic package of claim 11, further comprising:
a reservoir fluidically coupled to the well.

13. The electronic package of claim 12, wherein the reservoir is provided adjacent to the first pad and the second pad.

14. The electronic package of claim 12, wherein the reservoir is a channel into the layer.

15. The electronic package of claim 11, wherein the liquid metal has voids.

16. The electronic package of claim 15, wherein the voids account for up to approximately 20% of the volume of the liquid metal.

17. The electronic package of claim 11, wherein the first substrate is a package substrate and the second substrate is a board.

18. An electronic system, comprising:
a board with a first pad;
a package substrate with a second pad electrically coupled to the board by a liquid metal that contacts the first pad and the second pad; and
a die coupled to the package substrate.

19. The electronic system of claim 18, further comprising:
a layer between the board and the package substrate, wherein the layer comprises a well that confines the liquid metal.

20. The electronic system of claim 18, wherein the electronic system is part of a personal computer, a server, a mobile device, a tablet, or an automobile.
